(19) United States
(12) Patent Application Publication
(10) Pub. No.: US 2005/0266212 A1
(43) Pub. Date: Dec. 1, 2005

(54) Layered board and manufacturing method of the same, electronic apparatus having the layered board

(75) Inventors: Takashi Kanda, Kawasaki (JP); Kenji Fukuzono, Kawasaki (JP); Manabu Watanabe, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 10/997,973

(22) Filed: Nov. 29, 2004

(30) Foreign Application Priority Data
May 31, 2004 (JP) 2004-160517

(51) Int. Cl. B32B 3/00; H05K 1/00

(52) U.S. Cl. 428/209; 427/118; 174/250

(57) ABSTRACT

A manufacturing method of a layered board that includes a core layer that serves as a printed board, and a buildup layer that is electrically connected to said core layer, said buildup layer including an insulation part and a wiring part includes the step of setting a coefficient of thermal expansion, a thickness and a modulus of longitudinal elasticity of each layer so that the layered board has a predetermined value of the coefficient of thermal expansion.

This application claims the right of priority under 35 U.S.C. §119 based on Japanese Patent Application No. 2004-160517 filed on May 31, 2004, which is hereby incorporated by reference herein in its entirety as if fully set forth herein.

### BACKGROUND OF THE INVENTION

The present invention relates generally to a layered board and a manufacturing method of the same, and more particularly to a layered board that includes a core layer and a buildup layer at both surfaces of the core layer, which is also referred to as a “buildup board”, and a manufacturing method of the same.

The buildup boards have conventionally been used for laptop personal computers (“PCs”), digital cameras, servers, cellular phones, etc, to meet miniaturization and weight saving demands of electronic apparatuses. The buildup board uses a double-sided printed board or a multilayer printed board as a core, and adds an interfacially connected buildup layer (which is layers of an insulation layer and a wiring layer) to both surfaces or single surface of the core through the microvia technology. The double-sided lamination can maintain the warping balance. The microvia enables a through-hole connection to reduce a pad diameter and to make the board small and lightweight, the high-density wiring to reduce the cost, and the reduced via's diameter and length to improve electric characteristics, such as the parasitic capacity.

One known buildup board manufacturing method is a method for layering a buildup layer one by one on both surfaces of a core layer, as disclosed in Japanese Patent Application, Publication No. 2003-218519. In addition, Japanese Patent Application, Publication No. 2001-352171 and Multilayer Printed Wiring Board Internet <URL: http://industrial.panasonic.com/www-ctlg/ctlgi/qANE000_J.html> searched on May 23, 2004 teach use of conductive paste (or silver paste) to joint respective layers in Any Layer IVH (“ALIVH”). ALIVH applies to the entire layers an Inner Via Hole (“IVH”) structure that forms an interfacial connection of a multilayer board at an arbitrary location.

Other prior art include, for example, Japanese Patent Applications, Publication Nos. 2001-172606 and 2001-230551.

However, the conventional manufacturing method has a bad yield of the buildup board. The yield of the buildup board largely depends upon the yield of forming the buildup layer, and the percent defective increases during the layering process as the board is large and multilayer. This is because whether it is non-defective cannot be determined before the buildup board is completed. This method considers the entire buildup board to be defective even if only part of the buildup layer on one side is defective, thus wastes non-defective core layer and the buildup layer on the other side, and lowers the throughput.

In addition, the conventional manufacturing method cannot control the physical properties of the completed buildup board, such as a coefficient of thermal expansion, a modulus of longitudinal elasticity, and warping balance. For example, in order to apply the buildup board to a large tester board, such as an LSI wafer tester, it is necessary to make the coefficient of thermal expansion of a substrate close to that of the LSI (or silicon). Since it is known that the coefficient of thermal expansion of the buildup board largely depends upon the core material of the core layer, an attempt is proposed to make the coefficient of thermal expansion of the entire buildup board equivalent to that of silicon by making the core layer's coefficient of thermal expansion lower than that of silicon, and the buildup layer's coefficient of thermal expansion greater than that of silicon. Since this attempt requires skills and has a low precision, a method for easily controlling the coefficient of thermal expansion of the entire buildup board has been demanded. In addition, the small modulus of longitudinal elasticity means that the material is soft and has small rigidity, and sometimes cannot maintain intended rigidity and flatness, posing the similar problems to the coefficient of thermal expansion. While an attempt has conventionally been proposed which maintains the warping balance of the entire buildup board by forming the same multilayer buildup board on both side of the core layer and making each layer in the buildup layer be of the same structure (and physical properties) and size, it sometimes difficult to make each layer in the buildup layer be of the same structure and size. In this case, the buildup board disadvantageously warps.

### BRIEF SUMMARY OF THE INVENTION

Accordingly, it is an exemplary object to provide a layered board, its manufacturing method, and an electronic apparatus having the layered board, which improve the yield and/or provide desired physical properties, such as a coefficient of thermal expansion, a modulus of longitudinal elasticity, and warping balance.

A manufacturing method according to one aspect of the present invention of a layered board that includes a core layer that serves as a printed board, and a buildup layer that is electrically connected to said core layer, said buildup layer including an insulation part and a wiring part, includes the step of setting a coefficient of thermal expansion, a thickness and a modulus of longitudinal elasticity of each layer so that the layered board has a predetermined value of the coefficient of thermal expansion. The setting step preferably satisfies the following equation:

$$α = \frac{{\sum }_{n = 1}^{n} α n \cdot tn \cdot En}{{\sum }_{n = 1}^{n} tn \cdot En} \qquad ( 1 )$$

where α is the coefficient of thermal expansion of the layered board, αn is the coefficient of thermal expansion of each layer, tn is the thickness of each layer, and En is the modulus of longitudinal elasticity of each layer.

This manufacturing method can control the coefficient of thermal expansion of the layered board with high reproducibility.

A manufacturing method according to another aspect of the present invention of a layered board that includes a core layer that serves as a printed board, and a buildup layer that is electrically connected to said core layer, said buildup layer including an insulation part and a wiring part, includes the step of setting a modulus of longitudinal elasticity and a volume of each layer so that the layered board has a predetermined value of a modulus of longitudinal elasticity. The setting step preferably satisfies the following equation:

$$E = \frac{{\sum }_{n = 1}^{n} En \cdot Vn}{V} \qquad ( 2 )$$

where E is the modulus of longitudinal elasticity of the layered board, V is the volume of of the layered board, En is the modulus of longitudinal elasticity of each layer, and Vn is the volume of each layer.

This manufacturing method can control the modulus of longitudinal elasticity of the layered board with high reproducibility.

A manufacturing method according to another aspect of the present invention of a layered board that includes a core layer that serves as a printed board, and a buildup layer that is electrically connected to said core layer, said buildup layer including an insulation part and a wiring part, includes the steps determining whether the core layer is non-defective, determining whether the buildup layer is non-defective, and jointing the core layer that has been determined to be non-defective and the buildup layer together by heating and compressing the buildup layer on the core layer. The yield improves by determining the non-defectiveness before the manufacture of the layered board is completed and jointing the non-defective core layer and buildup layer together.

A layered board according to another aspect of the present invention includes a core layer that serves as a printed board, and a buildup layer that is electrically connected to said core layer, wherein said buildup layer includes an insulation part and a wiring part, wherein said buildup layer includes a first buildup layer jointed to a front side of said core layer, and a second buildup layer jointed to a rear side of said core layer, and wherein the first and second buildup layers have plural types of layers with different physical properties and have substantially the same thickness. Thereby, the warping balance of the layered board can be maintained.

A layered board according to another aspect of the present invention includes a core layer that serves as a printed board, and a buildup layer that is electrically connected to said core layer, wherein said buildup layer includes an insulation part and a wiring part, wherein said buildup layer includes a first buildup layer jointed to a front side of said core layer, and a second buildup layer jointed to a rear side of said core layer, and wherein the first and second buildup layers have different layered structures but have substantially the same coefficient of thermal expansion. The phrase “substantially the same” means that a difference is within ±5% between them.

An electronic apparatus including the above layered board also constitutes one aspect of the present invention.

Other objects and further features of the present invention will become readily apparent from the following description of the preferred embodiments with reference to accompanying drawings.

### BRIEF DESCRIPTION OF THE DRAWINGS

FIG. 1 is a flowchart for explaining a manufacturing method of a layered board according to the present invention.

FIGS. 2A-2E are schematic sectional views of steps in FIG. 1.

FIG. 3 is a flowchart for explaining the step 1100 in FIG. 1 in detail.

FIGS. 4A-4D are schematic sectional views of steps in FIG. 3.

FIG. 5 is a flowchart for explaining the step 1200 in FIG. 1 in detail.

FIGS. 6A-6G are schematic sectional views of steps in FIG. 5.

FIGS. 7A-7G are schematic sectional views of steps in FIG. 5.

FIG. 8 is a graph showing a relationship between the remelting temperature the soldered thickness used for the conductive adhesive in the step 1500 in FIG. 1.

FIG. 9 is a plane view of one exemplary electronic apparatus to which a layered board shown in FIG. 2E is applied.

FIG. 10 is a graph showing a relationship between the coefficient of thermal expansion of the core layer and the coefficient of thermal expansion of the layered board.

FIG. 11 is a graph showing a relationship between the coefficient of thermal expansion of the buildup layer and the coefficient of thermal expansion of the layered board.

FIG. 12 is a graph showing a relationship between the modulus of longitudinal elasticity of the core layer and the modulus of longitudinal elasticity of the layered board.

FIG. 13 is a graph showing a relationship between the modulus of longitudinal elasticity of the buildup layer and the modulus of longitudinal elasticity of the layered board.

FIG. 14 is a schematic sectional view showing an arrangement for maintained warping balance of the layered board when the buildup layer has plural layers having different physical properties.

FIG. 15 is a schematic sectional view showing an arrangement for maintained warping balance of the layered board when each of two buildup layers includes only one layer that has different physical properties.

FIG. 16 is a schematic sectional view showing an arrangement for maintained warping balance when each of two buildup layers has plural layers having different physical properties.

### DETAILED DESCRIPTION OF THE PREFERRED EMBODIMENTS

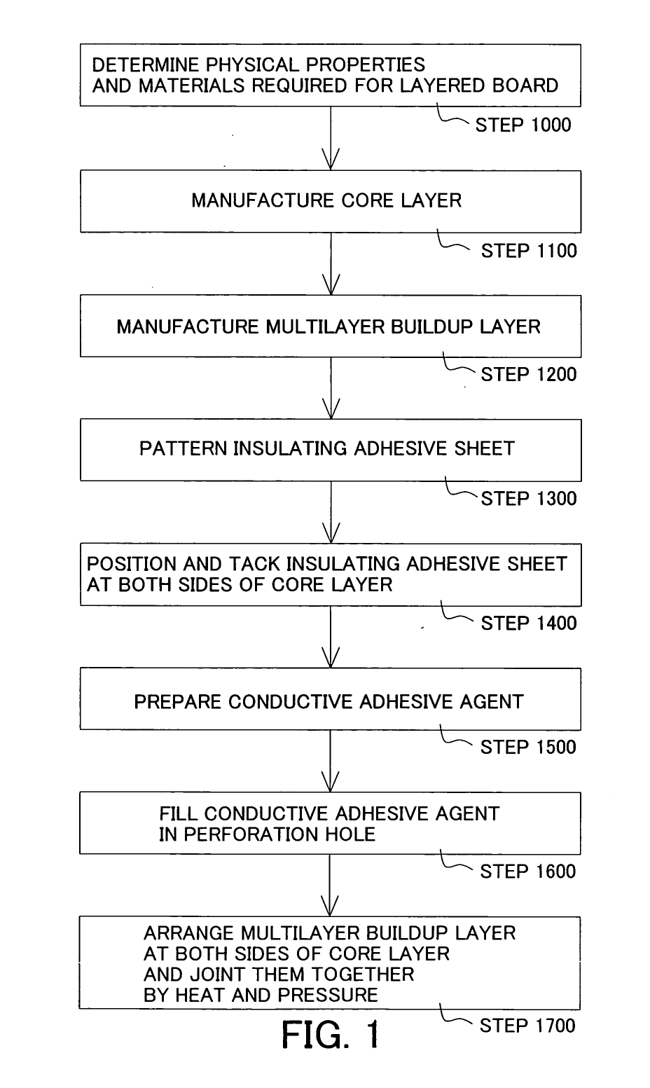

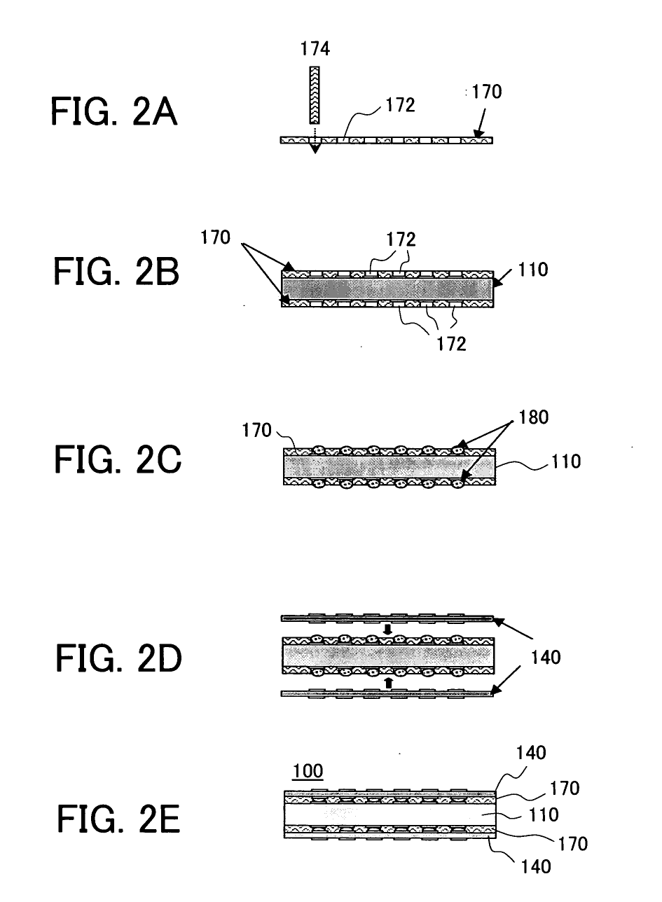

A description will be given of a manufacturing method of a layered board 100 according to one embodiment of the present invention. Here, FIG. 1 is a flowchart for explaining a manufacturing method of the layered board 100. FIG. 2 is a schematic sectional view of steps in FIG. 1. FIGS. 2A-2E are schematic sectional views of steps in FIG. 1.

First the physical properties and materials required for the layered board 100 are determined (step 1000). In this embodiment, the physical properties include a coefficient of thermal expansion, a modulus of longitudinal elasticity, and warping balance.

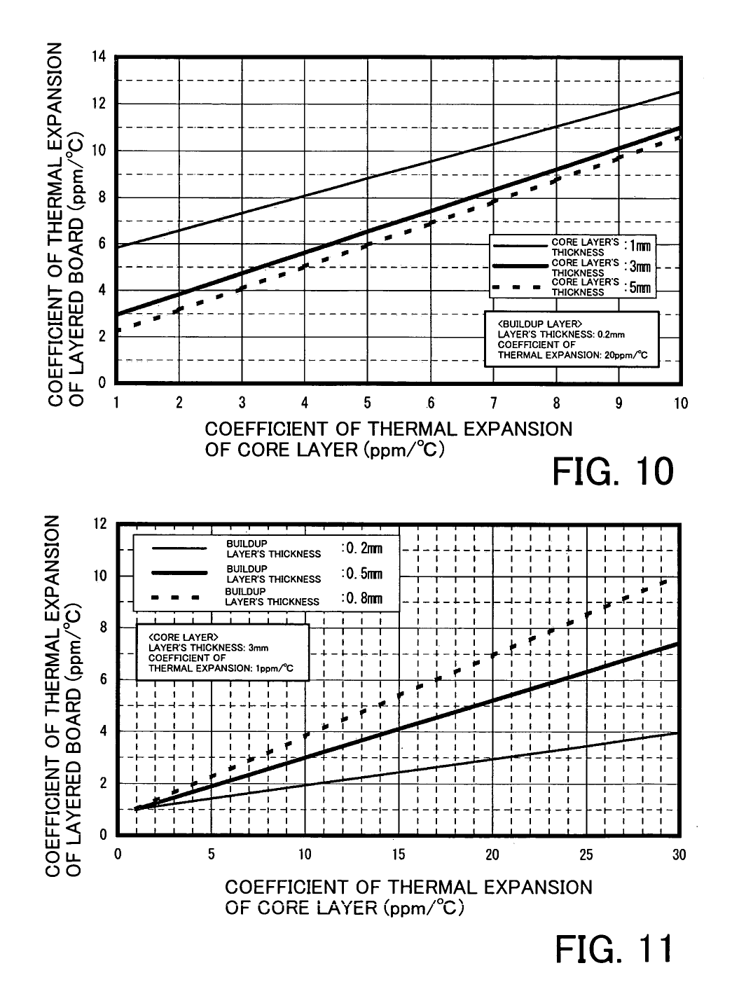

This embodiment sets a coefficient of thermal expansion, a thickness and a modulus of longitudinal elasticity of each layer so that the layered board has a predetermined value of the coefficient of thermal expansion. The coefficient of thermal expansion of the layered board 100 is calculated from FIG. 10, where the thickness and the coefficient of thermal expansion of the core layer are varied while the thickness and the coefficient of thermal expansion of the buildup layer 140 is fixed to 0.2 mm and 20 ppm ° C. In addition, the coefficient of thermal expansion of the layered board 100 is calculated from FIG. 11, where the thickness and the coefficient of thermal expansion of the buildup layer are varied while the thickness and the coefficient of thermal expansion of the core layer 140 is fixed to 3 mm and 1 ppm ° C. From the obtained data, the coefficient of thermal expansion of the layered board is set to satisfy the following equation:

$$α = \frac{{\sum }_{n = 1}^{n} α n \cdot tn \cdot En}{{\sum }_{n = 1}^{n} tn \cdot En} \qquad ( 1 )$$

where α is the coefficient of thermal expansion of the layered board, αn is the coefficient of thermal expansion of each layer, tn is the thickness of each layer, and En is the modulus of longitudinal elasticity of each layer. This method can control the coefficient of thermal expansion of the layered board 100 with high reproducibility.

In Equation (1), the coefficient of thermal expansion of each layer is controllable as well as the thickness of each layer, for example, by increasing and decreasing dummy copper wiring part. In general, a modulus of longitudinal elasticity of each layer is controlled by a selection of a material.

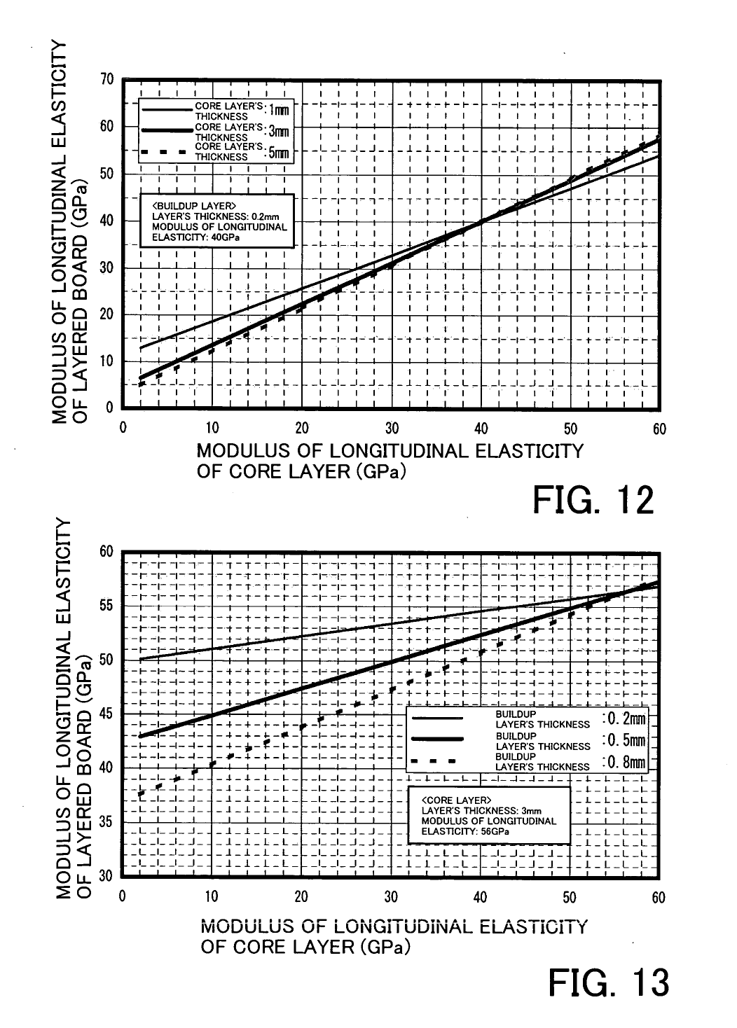

This embodiment also sets a modulus of longitudinal elasticity and a volume of each layer so that the layered board has a predetermined value of the modulus of longitudinal elasticity. The modulus of longitudinal elasticity of the layered board 100 is calculated from FIG. 12, where the thickness and the modulus of longitudinal elasticity of the core layer are varied while the thickness and the modulus of longitudinal elasticity of the buildup layer 140 is fixed to 0.2 mm and 40 GPa. In addition, the modulus of longitudinal elasticity of the layered board 100 is calculated from FIG. 13, where the thickness and the modulus of longitudinal elasticity of the buildup layer are varied while the thickness and the modulus of longitudinal elasticity of the core layer 140 is fixed to 3 mm and 56 GPa. From the obtained data, the coefficient of thermal expansion of the layered board is set to satisfy the following equation:

$$E = \frac{{\sum }_{n = 1}^{n} En \cdot Vn}{V} \qquad ( 2 )$$

where E is the modulus of longitudinal elasticity of the layered board, V is the volume of of the layered board, En is the modulus of longitudinal elasticity of each layer, and Vn is the volume of each layer. This manufacturing method can control the modulus of longitudinal elasticity of the layered board with high reproducibility.

In Equation (2), the volume of each layer is controllable. In general, a modulus of longitudinal elasticity of each layer is controlled by a selection of a material.

Next, in order to maintain the warping balance of the layered board 100, the instant embodiment sets a structure of the buildup layer 140 to be bonded to both sides of the core layer 110 as follows:

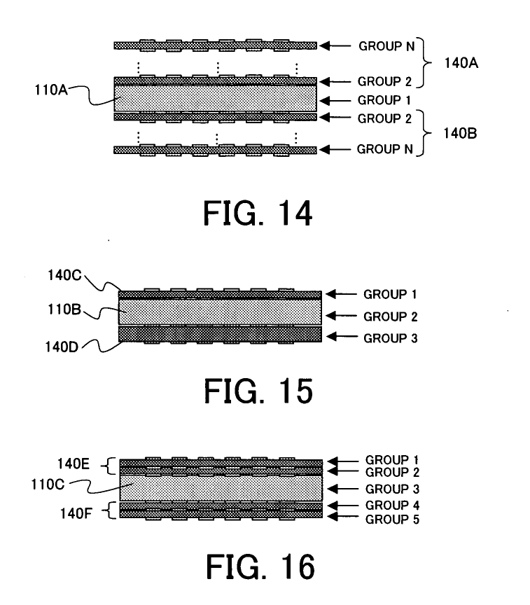

First, assume, as shown in FIG. 14, that a buildup layer 140A is to be jointed to the front side of the core layer 110A that has physical properties of Group 1, and a buildup layer 140A is to be jointed to the rear side of the core layer 110A. The buildup layers 140A and 140B include plural types of layers having different physical properties. In FIG. 14, Groups 2 to N denote different layers having different physical properties. This embodiment sets a layer having the same physical properties or Group to the same thickness, although the location is arbitrary, so as to equalize the coefficient of thermal expansion and longitudinal elasticity between the buildup layers 140A and 140B, the same it is necessary. Therefore, for example, layers having physical properties of Group 2 have the same thickness between the buildup layers 140A and 140B, although the layer may be the uppermost layer or an intermediate layer irrespective of the arrangement of FIG. 14. This is because Equations (1) and (2) does not address a location of each layer.

Next, assume, as shown in FIG. 15, that a buildup layer 140C is to be jointed to the front side of the core layer 110B that has physical properties of Group 2, and a buildup layer 140D is to be jointed to the rear side of the core layer 110B. The buildup layers 140C and 140D have different layer structures, and the thicknesses of both layers are determined so that the coefficient of thermal expansion is substantially the same in Equation (1). The phrase “substantially the same” means that a difference is within ±5% between them. 5% or higher would remarkably destroy the warping balance.

FIG. 16 includes an example where the buildup layers 140C and 140D in FIG. 15 include plural layers. The buildup layer 140E to be jointed to the front side of the core layer 110C and the buildup layer 140F to be jointed to the rear side of the core layer 110F have substantially the same coefficient of thermal expansion. In this case, the coefficient of thermal expansion of the buildup layer 140E is a composite coefficient of thermal expansion obtained from Equation (1).

It is understood that the warping balance of the layered board 100 can be maintained by making the composite coefficient of thermal expansion be substantially the same, when one buildup layer is a single layer and the other buildup layer includes plural layers or when both buildup layers have a layer of common physical properties and a layer of different physical properties.

As discussed above, the warping balance of the layered board 100 is maintained by making the coefficients of thermal expansion (and preferably the moduli of longitudinal elasticity) substantial the same between two buildup layers 140.

Next, turning back to FIG. 1, a core layer 110 is manufactured (step 1100). The core layer 110 of the instant embodiment has a low coefficient of thermal expansion approximately equivalent to that of silicon (about 4.2×10⁻⁶/° C.), but the present invention does not limit the coefficient of thermal expansion. The core layer 110 has a rectangular or cylindrical shape in this embodiment, and four positioning holes (for example, at the corners of the rectangle) on the front and back surfaces. The core layer has a core and a through-hole, and may or may not include a layered structure on both sides of the core. In general, a pitch of the layered structure is greater than the interlaminar pitch of the buildup layer 140.

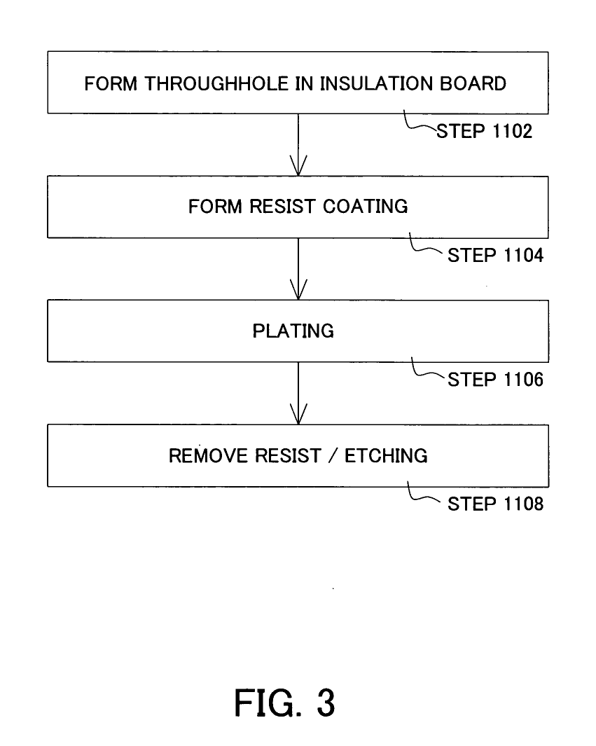

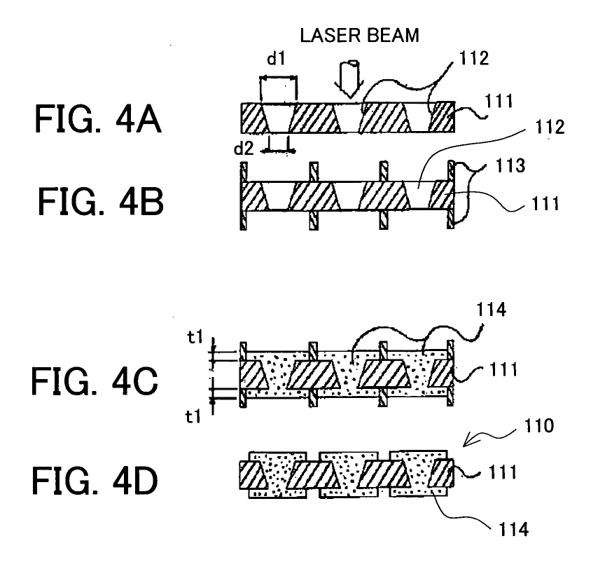

A detailed description will be given of the manufacture of the core layer 110, with reference to FIGS. 3 and 4. Here, FIG. 3 is a flowchart for explaining a manufacturing method of the core layer 110. FIGS. 4A-4D are schematic sectional views of steps in FIG. 3. A description will now be given of an exemplary manufacture method of the core layer 110 that does not have a layered structure.

First, a perforation hole 112 is formed, as shown in FIG. 4A, in an insulation board 111 through laser processing (step 1102). The insulation board 111 is made, for example, of glass cloth epoxy resin base material, glass cloth bsmaleimide-triazine resin base material, glass cloth poly phenylene ether resin base material, aramid polyimid liquid crystal polymer base material, etc. The perforation hole 112 serves as a through-hole. The insulation board 111 prepared in the instant embodiment is a thermoset epoxy resin base material with a thickness of about 50 μm. The laser processing uses, for example, a pulsed oscillation carbon dioxide laser processing unit, with the processing condition, for example, of a pulsed energy of 0.1 to 1.0 mJ, a pulsed width of 1 to 100 μs, and the number of shots between 2 to 50. The perforation hole 112 made by the laser processing has a diameter d1 of about 60 μmΦ, and a diameter d2 of about 40 μmΦ. Thereafter, in order to remove residual resin in the perforation hole 112, the desmear process follows, such as an oxygen plasma discharge process, a corona discharge process, a potassium permanganate process, etc. Moreover, the electroless plating is applied to the inside of the perforation hole 112 and the entire front and back surfaces of the insulation board 111. A coating thickness of the electroless plating is about 4500 Å.

Next, a dry film resist 113 is provided on front and rear surfaces of the insulation board 111 as shown in FIG. 4B (step 1104). This dry film resist 113 is, for example, of an alkali development type and photosensitivity. A thickness of the dry film resist 113 is, for example, about 40 μm. Exposure and development using the dry film resist 113 provides a desired pattern of resist coating.

The plating process follows as shown in FIG. 4C (step 1106). The plating process employs the DC electrolysis plating that utilizes the electroless plating layer provided in the step 1102 (FIG. 4A) as an electrode. The plating layer 114 is made of copper, tin, silver, solder, copper/tin alloy, copper/silver alloy, etc., and any type is applicable as long as it is metal that can be plated. The insulation board 111 with the dry film resist 113 obtained in the step 1104 is soaked in the plating bath tab. The plating layer 114 grows and increases its thickness on the inner surface of the perforation hole 112 and on the entire front and back surfaces of the insulation board 111. As the thickness of the plating layer 114 increases, the plating layer 114 grows from the bottom surface part to the layer surface part of the perforation hole 112 and fills the bottom surface part of the of the perforation hole 112.

The plating continues until the thickness t1 of the plating layer 114 on the front and back surfaces of the insulation board 111 becomes, for example, about 60 μm, and the insulation substrate 111 including the perforation hole 112 has the flat front and back surfaces.

Thereafter, etching and resist removal follow (step 1108). The etching is to smoothen the rough plating layer 114 on both the front and back surfaces of the insulation board 111 and to adjust a thickness of the plating layer 114 on both the front and back surfaces. A usable etchant is copper chloride. The dry film resist 113 provided on the front and rear surfaces is then removed, as shown in FIG. 4D, by the release agent, which is, for example, an alkali release agent. As a result, the electroless plating exposes, which has been provided in step 1102, as a layer under the dry film resist 113 that has been removed. Then, this electroless plating is etched. A usable etchant is, for example, hydrogen persulfate.

The insulation board 111 may have a layered structure. For example, the insulation board 111 has second and third insulation boards at both sides of the first insulation board. The first insulation board is made of alamid or epoxy resin and set to have a thickness of about 25 μm and a heat decomposition temperature of about 500° C. The second and third insulation boards are made of thermoset epoxy resin, and set to have a thickness of about 12.5 μm and a heat decomposition temperature of about 300° C. The laser processing in the step 1102 can make different hole diameters of the perforation hole 112. The hole diameter in the second and third insulation boards having a lower heat decomposition is larger than that of the first insulation board. The perforation hole 112 has a section with an approximately X shape, rather than a trapezium shape shown in FIG. 4B. Thereby, the plating layer 114 grows from the upper and lower sides of the insulation board 111 at the same time, shortening the processing time period rather than growing only on one surface as shown in FIG. 4C.

Whether the core layer 110 is non-defective is determined before the core layer 110 and the buildup layer 140 are jointed together, and only the non-defective one is used for the step 1700.

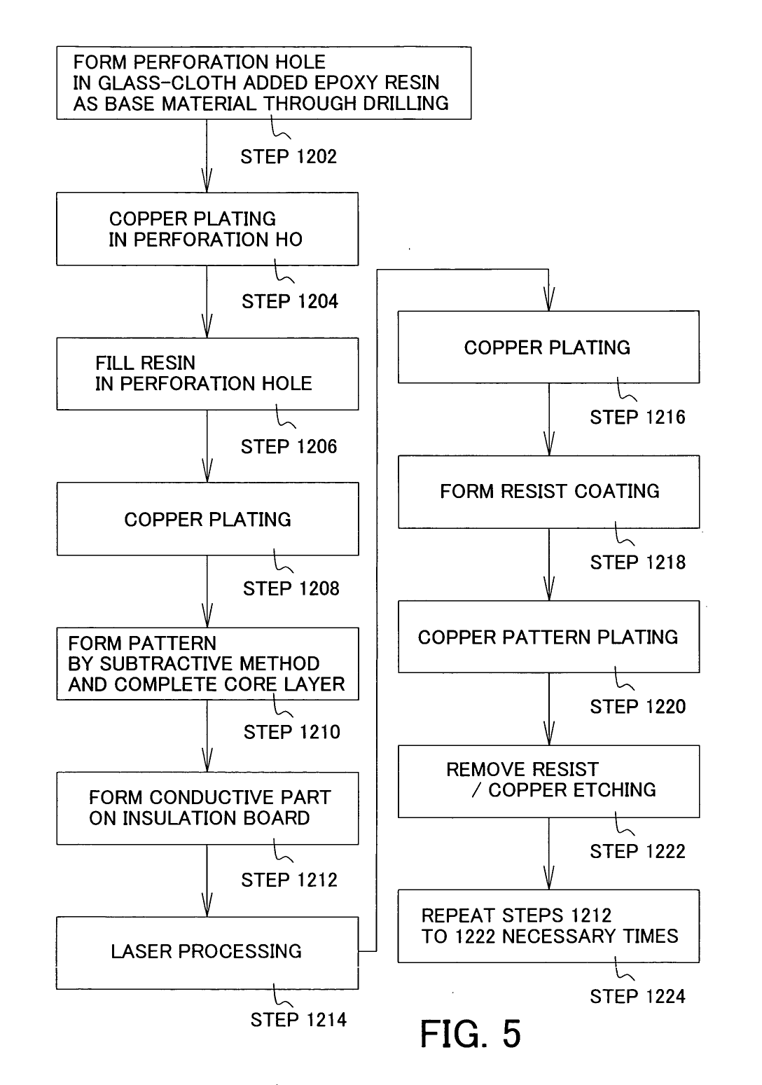

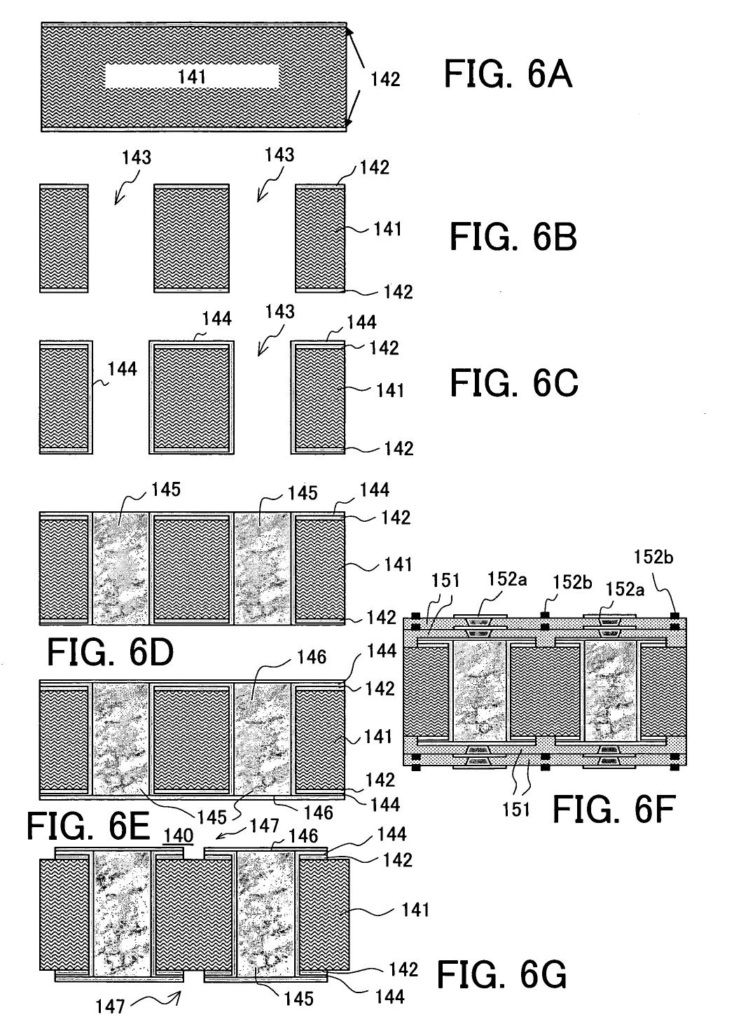

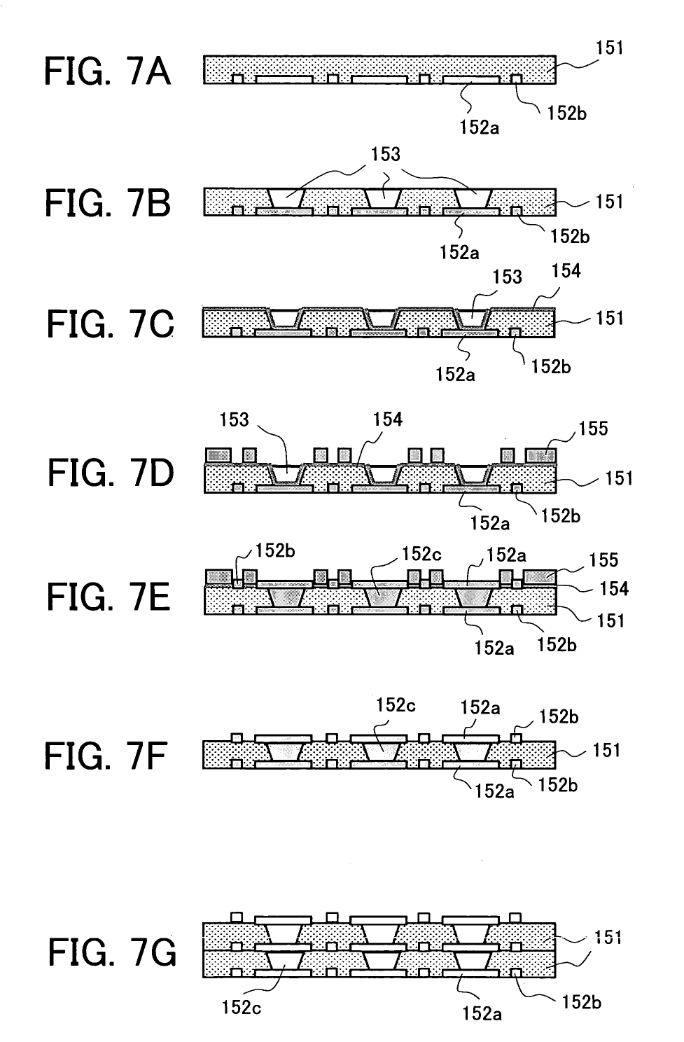

Next, the multilayer buildup layer 140 is manufactured (step 1200). The buildup layer 140 has a rectangular or cylindrical shape in this embodiment, and four positioning holes (for example, at the corners of the rectangle) on the front and back surfaces. The core layer has an insulating part and a wiring part, and is connected electrically to the core layer 110. The buildup layer 140 has a layered structure and may or may not include a core. A description will be given of a manufacture example of a buildup layer that includes the core, with reference to FIGS. 5-7. Here, FIG. 5 is a flowchart for explaining the manufacturing method of the buildup layer 140, and FIGS. 6A-6G are schematic sectional views of steps for manufacturing the core part in FIG. 5. FIGS. 7A-7G are schematic sectional views of steps for manufacturing the layered part in FIG. 5.

The core part of the buildup layer 140 is initially produced.

As shown in FIG. 6A, epoxy resin 141 that contains glass cloth is prepared as a base material, and a perforation hole 143 is formed to maintain the conductivity between the front and back surfaces by drilling as shown in FIG. 6B (step 1202). Next, copper plating 114 is applied, as shown in FIG. 6C, to the inside of the perforation hole 143 (step 1204). Next, as shown in FIG. 6D, resin 145 fills the perforation hole 143 (step 1206). Next, copper plating 146 called lid plating is applied, as shown in FIG. 6E, to a front surface (step 1208). Finally, the core layer 110 is completed, as shown in FIG. 6F, by forming a pattern 147 through etching according to the subtractive method (step 1210).

Next, the buildup layer 140 is completed by forming a layered part on both sides of the core part.

First, as shown in FIG. 7A, a conductive part 152a corresponding to a through-hole 112 of the core layer 110 and a conductive part 152b for a wiring part are formed in the insulation board 141 through copper plating (step 1212). Next, as shown in FIG. 7B, a hole 153 is formed that expose the copper plating 152a (step 1214). Next, as shown in FIG. 7C, an electroless plating 154 is applied (as shown in step 1216). Next, as shown in FIG. 7D, a resist coating 155 is formed which has openings in place corresponding to the conductive parts 152a and 152b (step 1218). Next, as shown in FIG. 7E, copper pattern plating is applied (step 1220). As a result, the conductive parts 152a and 152b are formed on the insulation board 151 and the hole 153 is filled with the conductive part 152c. Next follows resist removal and copper etching, as shown in FIG. 7F (step 1222). Next, as shown in FIG. 7G, steps 1212 to 1222 are repeated to form the buildup layer 140 having the necessary number of layers. Finally, as shown in FIG. 6G, the buildup layer 140 is completed by repeating steps in FIGS. 7A-7G on the front and back surfaces of the core part shown in FIG. 6F. Whether the buildup layer 140 is non-defective is determined before the buildup layer 140 and the core layer 110 are jointed together, and only the non-defective one is used for the step 1700.

Next, as shown in FIG. 2A, the insulation adhesive sheet 170 is patterned (step 1300). The insulating adhesive sheet 170 is made, for example, of epoxy resin, and various types of insulating adhesive sheets are commercially available. The epoxy resin is heat-hardening adhesive and hardens at 150° C. However, the epoxy resin soften at about 80° C. and contacts the core layer 110, exhibiting a provisional fixation effect.

The height of the insulating adhesive sheet 170 determines an amount of the conductive adhesive 180. A perforation hole 172 is formed in the insulating adhesive sheet by a drill 174 at a position that electrically connects the core layer 110 with the buildup layer 140. While FIGS. 2A-2E provide the perforation holes 172 at regular intervals, this arrangement is exemplary. The insulating adhesive sheet 170 has a rectangular or circular shape in the instant embodiment, and four positioning holes (for example, at the corners of the rectangle) on the front and back surfaces.

Next, as shown in FIG. 2B, a pair of insulating adhesive sheet 170 is positioned and provisionally fixed at the both sides of the core layer 110 (step 1400). A perforation hole 172 is positioned at a position that electrically connects the core layer 110 to the buildup layer 140 or an electric connection pad part. This embodiment positions the core layer 110 and the insulating adhesive sheet 170 with each other by aligning their positioning holes and inserting pins into them. Thus, this embodiment utilizes mechanical positioning means, but the present invention does not limit the positioning means. For example, optical means and alignment marks may be used instead.

The adhesive sheet 170 is preliminarily heated, for example, up to about 80° C., and provisionally fixed onto the core layer 110. The positioning pins are pulled out after heating. While the instant embodiment positions and provisionally fixes the core layer 110 and the adhesive sheet 170 with each other, the buildup layer 140 may be tentatively fixed and fixed.

Next, the conductive adhesive 180 is prepared (step 150). The conductive adhesive contains metallic particles in an adhesive, such as epoxy resin. Each metallic particle has a first melting point, serves as a filler, and is plated with solder having a second melting point lower than the first melting point. The epoxy resin adhesive as a base material in the conductive adhesive 180 of the present invention has the heat-hardening temperature is 150° C. The metallic particle, such as Cu, Ni, etc., has a high melting point and its melting point is preferably higher than the heat-hardening temperature of the adhesive as a base material, so as to prevent the adhesive from heat-hardening before the solder melts.

Thus, the conductive adhesive 180 is an adhesive that contains a conductive filler that includes as a core metallic particles with a high melting point, which is plated with low-temperature solder. Powders of metallic particles with various are commercially available. The instant embodiment applies electroless plating to a surface of a metallic particle. A plated thickness on the surface of the metallic particle is, for example, controllable by the soaking time period in the solution. Of course, the present invention does not limit the plating method.

The conductive adhesive 180 of the instant embodiment has some parameters to be satisfied, such as the conductivity, the melting temperature, the remelting temperature, and bonding force. The insufficient conductivity makes unstable the electric connection between the core layer 110 and the buildup layer 140, and deteriorates the electric characteristic of the layered board 100. The high melting temperature increases the thermal stress and strain that work between the core layer 110 and the buildup layer 140 or that affect the conductive adhesive 180, and both layers and the conductive adhesive 180 undesirably get damaged. Therefore, the low melting temperature is preferable. The low remelting temperature undesirably causes melting of the conductive adhesive 180 and weakens the bonding force and the conductivity when the subsequent process mounts another circuit device onto the layered board 100. Therefore, the remelting temperature is preferably 250° C. or higher. The bonding force is preferably stronger than the silver paste used for the conventional silver filler so as to maintain stable the conductivity and layered structure.

The conductivity of the conductive adhesive 180 depends upon the filler content and a solder amount. It is necessary to control these amounts in order to maintain the predetermined conductivity.

The melting temperature of the conductive adhesive 180 is the melting point of the plating. The instant embodiment uses the low-temperature solder consisting of Sn—Bi that has the melting temperature of 138° C.

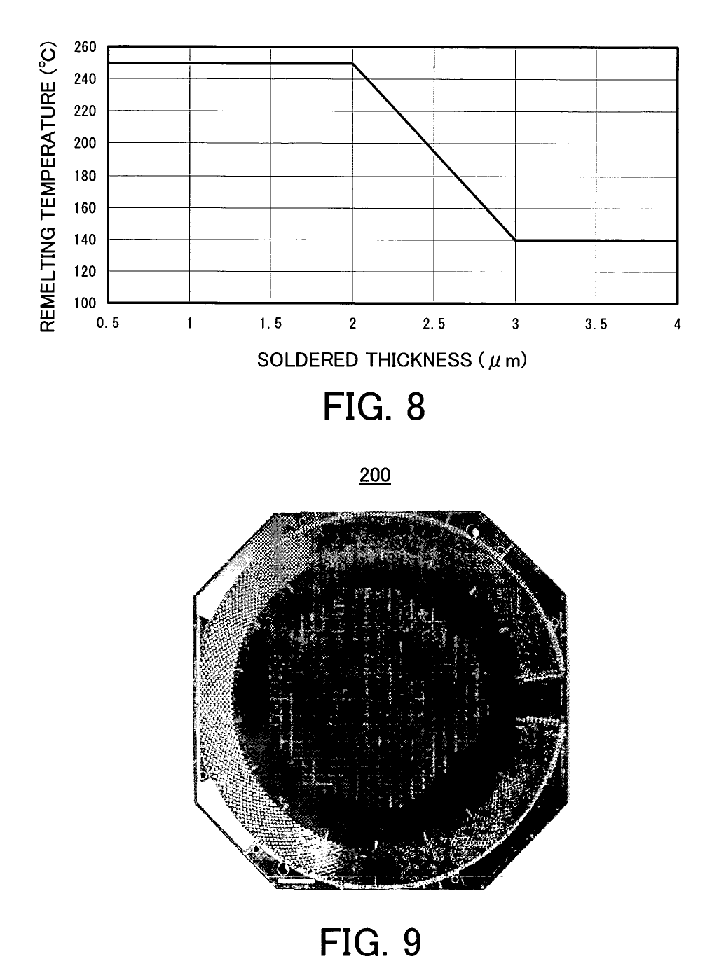

The remelting temperature of the conductive adhesive 180 is controllable by controlling the plated thickness and filler's particle diameter. FIG. 8 shows a relationship between the Sn—Bi plated thickness and the remelting temperature when the filler (Cu) content is 90% and the particle diameter is between Φ20 to 40 μm. When the plated thickness exceeds 2 μm, solder insufficiently diffuses and thus remains. Therefore, the remelting temperature reduces down to about the melting point of Sn—Bi. Conversely, the plated thickness of 2 μm or smaller enables Sn—Bi to completely diffuse and makes the remelting temperature almost constant.

On the other hand, the plated thickness defines the bonding force of the conductive adhesive 180. The silver filler lowers the bonding force in the silver paste of the conventional ALIVH, whereas the instant embodiment maintains the bonding force through the solder plating. The bonding force increases as the soldering amount increases. However, the large solder amount undesirably lowers the remelting temperature as discussed above. Therefore, the plated thickness should be determined so that the conductive adhesive 180 reconcile the predetermined junction strength with remelting temperature (reliability).

The graph shown in FIG. 8 moves to the right as the particle diameter is greater than 40 μm, and moves to the left as the particle diameter is smaller than 20 μm. In general, metallic particle having particle diameters of 100 μm or smaller, which is used as fillers, can maintain predetermined bonding strength if the Sn—Bi plated thickness is 1 μm or greater.

The graph shown in FIG. 8 changes according to used types of fillers and solders. While the conductive adhesive 180 of the instant embodiment has some parameters to be satisfied as discussed so as to make the coefficient of thermal expansion of the layered board 100 equivalent to that of silicon, the extent of the conductive adhesive 180's parameters to be satisfied varies if there is no such purpose. A type and thickness of the above solder plating, and filler's type, particle diameter and content are properly selected according to these parameters.

The conductive adhesive 180 includes hardener that contains one of carboxyl, amine and phenol, and organic acid that contains carboxylic acid of one of adipic acid, succinic acid and sebacic acid. Thereby, the solder's activation (or wetting performance) improves, i.e., the permeability into the core layer improves while preventing oxidation.

Next, as shown in FIG. 2C, the conductive adhesive 180 fills the perforation hole 172 (step 1600). This embodiment uses screen printing with a metal mask for filling, but the present invention does not limit a type of the filling method.

Next, the multilayer buildup layer 140 is positioned at both sides of the core layer 110, and jointed to the core layer through heat and pressure (step 1700). The positioning in the instant embodiment is similar to the positioning between the core layer 110 and the adhesive sheet 170, i.e., by aligning positioning holes in the adhesive sheet 170 with positioning holes in the buildup layer 140 and inserting pins into these positioning holes. The heating and compression are conducted through pressing under a vacuum environment, as referred to as a vacuum laminate.

The instant embodiment not only determines whether the core layer 110 is non-defective but also determines whether the buildup layer 140 is non-defective, before jointing the core layer 110 and the buildup layer 140 together, and uses only the non-defective core layer 110 and the non-defective buildup layer 140 for the joint in the step 1700. The yield improves by determining non-defectiveness before the manufacture of the layered board 100 is completed.

The instant embodiment uses the low-temperature solder, and the solder melts at a melting point lower than that of normal solders. The lower melting point reduces the thermal stress and strain that work between the core layer 110 and the buildup layer 140 when the temperature returns to the room temperature from the high temperature, preventing damages of both layers and junction layer. In addition, the high melting point metallic particles makes the melting point of the conductive adhesive 180 higher than that of the low-temperature solder, and thus makes the remelting temperature higher. As a result, the conductive adhesive 180 does not remelt or the reliability of adhesion does not reduce, even when the subsequent process mounts a circuit device. The metallic particles maintain the conductivity between the core layer 110 and the buildup layer 140.

FIG. 2E shows a completed layered board 100. The buildup layers 170 are arranged at both sides of the core layer 110 and maintain the warp balance.

FIG. 9 shows a top view of a tester board 200 for LSI wafers, to which the layered board 100 is applied.

### EXAMPLE 1

First, desired coefficient of thermal expansion and modulus of longitudinal elasticity are set to 3 ppm/° C. and 55 GPa. When the coefficients of thermal expansion of the core layer 110 and the buildup layer 140 were 1 ppm/° C. and 20 ppm/° C., respectively, their thicknesses were set to 3 mm and 0.2 mm, and their moduli of longitudinal elasticity were set to 56 GPa and 48 GPa, the layered board 100 could have designed coefficient of thermal expansion and modulus of longitudinal elasticity.

The conductive adhesive 180 of the present invention is broadly applicable to joints of two members having different coefficients of thermal expansion in an electronic apparatus. For example, these two members are an exoergic circuit device, such as a CPU, and a transmission member, such as a heat spreader and a heat sink, which transmits the heat from the exoergic circuit device. This structure can lower the temperature for junction, and prevents remelting when the exoergic circuit device heats. Epoxy resin used for the conductive adhesive 180 strongly joints the CPU and transmission member together, efficiently transmits the heat from the CPU to the transmission member, and radiates the CPU.

Further, the present invention is not limited to these preferred embodiments, and various variations and modifications may be made without departing from the scope of the present invention. For example, the electronic apparatus of the present invention is not limited to tester for LSI wafers, but is broadly applicable to laptop PCs, digital cameras, servers, and cellular phones.

Thus, the present invention can provide a layered board, its manufacturing method, and an electronic apparatus having the layered board, which improve the yield and/or provide desired physical properties, such as a coefficient of thermal expansion, a modulus of longitudinal elasticity, and warping balance.

1. A manufacturing method of a layered board that includes a core layer that serves as a printed board, and a buildup layer that is electrically connected to said core layer, said buildup layer including an insulation part and a wiring part, said manufacturing method comprising the step of setting a coefficient of thermal expansion, a thickness and a modulus of longitudinal elasticity of each layer so that the layered board has a predetermined value of the coefficient of thermal expansion.

2. A manufacturing method according to claim 1, wherein said setting step satisfies the following equation:
$$α = \frac{{\sum }_{n = 1}^{n} α n \cdot tn \cdot En}{{\sum }_{n = 1}^{n} tn \cdot En}$$
where α is the coefficient of thermal expansion of the layered board, αn is the coefficient of thermal expansion of each layer, tn is the thickness of each layer, and En is the modulus of longitudinal elasticity of each layer.

3. A manufacturing method of a layered board that includes a core layer that serves as a printed board, and a buildup layer that is electrically connected to said core layer, said buildup layer including an insulation part and a wiring part, said manufacturing method comprising the step of setting a modulus of longitudinal elasticity and a volume of each layer so that the layered board has a predetermined value of a modulus of longitudinal elasticity.

4. A manufacturing method according to claim 3, wherein said setting step satisfies the following equation:
$$E = \frac{{\sum }_{n = 1}^{n} En \cdot Vn}{V}$$
where E is the modulus of longitudinal elasticity of the layered board, V is the volume of of the layered board, En is the modulus of longitudinal elasticity of each layer, and Vn is the volume of each layer.

5. A manufacturing method of a layered board that includes a core layer that serves as a printed board, and a buildup layer that is electrically connected to said core layer, said buildup layer including an insulation part and a wiring part, said manufacturing method comprising the steps:
determining whether the core layer is non-defective;
determining whether the buildup layer is non-defective; and
jointing the core layer that has been determined to be non-defective and the buildup layer together by heating and compressing the buildup layer on the core layer.

6. A layered board comprising:
a core layer that serves as a printed board; and
a buildup layer that is electrically connected to said core layer,
wherein said buildup layer includes an insulation part and a wiring part, wherein said buildup layer includes a first buildup layer jointed to a front side of said core layer, and a second buildup layer jointed to a rear side of said core layer, and
wherein the first and second buildup layers have plural types of layers with different physical properties and have substantially the same thickness.

7. A layered board comprising:
a core layer that serves as a printed board; and
a buildup layer that is electrically connected to said core layer,
wherein said buildup layer includes an insulation part and a wiring part, wherein said buildup layer includes a first buildup layer jointed to a front side of said core layer, and a second buildup layer jointed to a rear side of said core layer, and
wherein the first and second buildup layers have different layered structures but have substantially the same coefficient of thermal expansion.

8. An electronic apparatus comprising a layered board, wherein said layered board includes:
a core layer that serves as a printed board; and
a buildup layer that is electrically connected to said core layer,
wherein said buildup layer includes an insulation part and a wiring part, wherein said buildup layer includes a first buildup layer jointed to a front side of said core layer, and a second buildup layer jointed to a rear side of said core layer, and
wherein the first and second buildup layers have plural types of layers with different physical properties and have substantially the same thickness.

9. An electronic apparatus comprising a layered board, wherein said layered board includes:
a core layer that serves as a printed board; and
a buildup layer that is electrically connected to said core layer,
wherein said buildup layer includes an insulation part and a wiring part, wherein said buildup layer includes a first buildup layer jointed to a front side of said core layer, and a second buildup layer jointed to a rear side of said core layer, and
wherein the first and second buildup layers have different layered structures but have substantially the same coefficient of thermal expansion.
